(19) United States
(12) Patent Application Publication
(10) Pub. No.: US 2020/0381185 A1
(43) Pub. Date: Dec. 3, 2020

(54) METHOD FOR PREPARING HOLE TRANSPORTING MATERIAL FOR PEROVSKITE SOLAR CELL WITH IMPROVED LONG-TERM STABILITY, HOLE TRANSPORTING MATERIAL FOR PEROVSKITE SOLAR CELL PREPARED THEREBY, AND PEROVSKITE SOLAR CELL INCLUDING THE SAME

(71) Applicant: Kookmin University Industry Academy Cooperation Foundation, Seoul (KR)

(72) Inventors: In Hwan JUNG, Seoul (KR); Sung Yeon JANG, Namyangju (KR); Randi AZMI, Seoul (KR); Jun Ho KIM, Ansan (KR)

(21) Appl. No.: 16/668,457

(22) Filed: Oct. 30, 2019

(30) Foreign Application Priority Data
May 30, 2019 (KR) 10-2019-0064047

(51) Int. Cl. H01G 9/20; H01G 9/00; H01L 51/00; C07F 1/08

(52) U.S. Cl. CPC H01G 9/2018; H01G 9/0036; H01G 9/2009; H01L 51/4253; C07F 1/08; H01L 51/0077; H01L 51/0007; H01L 51/0078

(57) ABSTRACT

The present invention relates to a method for preparing a hole transporting material for a perovskite solar cell with improved long-term stability, a hole transporting material for a perovskite solar cell prepared thereby, and a perovskite solar cell including the same, and more particularly, to a method for preparing a hole transporting material for a hole transporting material for a perovskite solar cell, which has high hole mobility, and thus is excellent in power conversion efficiency and may simultaneously realize excellent long-term stability, a hole transporting material for a perovskite solar cell prepared thereby, and a perovskite solar cell which includes the same, and thus may simultaneously realize excellent power conversion efficiency and long-term stability.

### CROSS-REFERENCE TO RELATED APPLICATION

This application claims priority to and the benefit of Korean Patent Application No. 10-2019-0064047, filed on May 30, 2019, the disclosure of which is incorporated herein by reference in its entirety.

### BACKGROUND

### 1. Field of the Invention

The present invention relates to a method for preparing a hole transporting material for a perovskite solar cell with improved long-term stability, a hole transporting material for a perovskite solar cell prepared thereby, and a perovskite solar cell including the same, and more particularly, to a method for preparing a hole transporting material for a hole transporting material for a perovskite solar cell, which has high hole mobility, and thus is excellent in power conversion efficiency and may simultaneously realize excellent long-term stability, a hole transporting material for a perovskite solar cell prepared thereby, and a perovskite solar cell which includes the same, and thus may simultaneously realize excellent power conversion efficiency and long-term stability.

### 2. Discussion of Related Art

Recently, studies on a perovskite solar cell to which a photoactive material having an organic and inorganic perovskite structure is applied as a next-generation solar cell have been actively conducted. After an organic and inorganic hybrid perovskite material was first applied to a solar cell by the Tsutomu Miyasaka group in Japan, the material has drawn attention as a light absorption material of a solar cell due to the characteristics that the material has a high extinction coefficient and can be easily synthesized by a solution process.

A material having a perovskite structure (ABX3) is an inorganic metal oxide.

The inorganic metal oxide is generally, as an oxide, a material in which cations of a metal (an alkali metal, an alkaline earth metal, a transition metal, a lanthanum group, and the like) such as titanium (Ti), strontium (Sr), calcium (Ca), cesium (Cs), barium (Ba), yttrium (Y), gadolinium (Gd), lanthanum (La), iron (Fe), and manganese (Mn) having different sizes are positioned at the A and B positions, an oxygen anion is positioned at the X position, and the metal cations of the B position are bonded to the oxygen anions of the X position in the form of a corner-sharing octahedron of 6-fold coordination. Examples thereof include strontium ferrite (SrFeO₃), lanthanum manganite (LaMnO₃), calcium ferrite (CaFeO₃), and the like.

In an organic and inorganic hybrid halide perovskite, an organic ammonium (RNH₃) or alkali metal cation is positioned at the A position and a halide (Cl, Br, I) is positioned at the X position in the ABX3, thereby forming a halide perovskite material.

Since the organic and inorganic hybrid halide perovskite (or the organic metal and inorganic metal halide perovskite) has an organic plane (or an alkali metal plane) and an inorganic plane stacked alternately, and thus is similar to a lamellar structure and can constrain excitons in the inorganic plane, the organic and inorganic hybrid halide perovskite may inherently become an ideal light emitting body that emits light of very high color purity by the crystal structure itself of the material rather than by the size of the material.

As a hole transporting material of a perovskite solar cell, Spiro-OmeTAD, which is a spiro compound, was developed and has been widely used, and the material is excellent in hole mobility, and thus significantly improved the performance of the perovskite solar cell such that a power conversion efficiency reached 23%. However, Spiro-OMeTAD has a disadvantage in that when a light-harvesting reaction is performed by exposing Spiro-OMeTAD to sunlight for a long period of time due to the structural characteristics of the material itself, the aforementioned power conversion efficiency is gradually decreased, and thus, the performance thereof deteriorates.

Therefore, there is an urgent need for developing a technology that replaces Spiro-OMeTAD by developing a stable hole transporting material which has other structural characteristics, and thus is stable while exhibiting excellent power conversion efficiency even though it is used for a long period of time.

### PRIOR ART DOCUMENT

### Patent Document

(Patent Document 0001) Korean Patent Application Laid-Open No. 10-2009-0131461 (published on Dec. 29, 2009)

### Non-Patent Document

(Non-Patent Document 0001) Akihiro Kojima et al., “Organometal Halide Perovskites as Visible-Light Sensitizers for Photovoltaic Cells”, Apr. 14, 2009, Journal of the American Chemical Society.

### SUMMARY OF THE INVENTION

A first object of the present invention is to provide a hole transporting material for a perovskite solar cell, which is capable of realizing both high hole mobility and excellent long-term stability.

Further, a second object of the present invention is to provide a hole transporting material, which is capable of preparing a perovskite solar cell having high hole mobility and excellent long-term stability through the above-described method.

In addition, a third object of the present invention is to provide a perovskite solar cell having high power conversion efficiency and excellent long-term stability.

The present invention has been devised as a result of research for achieving the above-described objects, and in order to achieve the first object, the present invention provides a hole transporting material for a perovskite solar cell, which includes a compound represented by the following Formula 1.

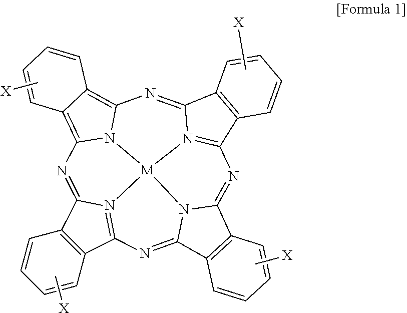

In Formula 1, M is at least one or more metals selected from copper (Cu), zinc (Zn), and cobalt (Co), and X is an electron donating group and each independently includes at least one functional group selected from a C₁₋₁₂ alkyl group consisting of primary to tertiary carbon, benzene, a secondary to tertiary amine group, and a C₁₋₆ linear alkoxy group.

In a preferred example of the present invention, a separate dopant may not be included in the hole transporting material.

In another preferred example of the present invention, the compound represented by Formula 1 may satisfy all of the following Conditions 1) to 3).

$$\begin{matrix}\frac{{n}_{{c}_{π}}}{{n}_{c}} \geq 70 \% & 1 ) \\ 1 \leq {n}_{A} - {N}_{An} \leq 40 & 2 )\end{matrix}$$

3) there is no quaternary carbon in the molecule

In Conditions 1) and 2), n_{c} indicates the total number of carbon atoms, n_{cπ} indicates the number of carbon atoms forming a π bond, n_{A} indicates the total number of atoms except for hydrogen, and n_{Aπ} indicates the number of atoms forming a π bond among the total atoms except for hydrogen.

In still another preferred example of the present invention, X may each independently have a structure represented by the following Formula 2.

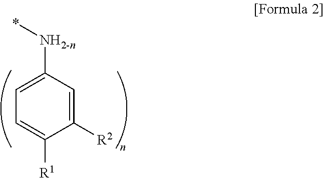

In Formula 2, * is a dangling bond, R₁ and R₂ are each independently hydrogen or a C₁₋₆ linear alkoxy group, and n is 1 or 2.

In yet another exemplary example of the present invention, the hole transporting material may include at least one selected from compounds represented by the following Formulae 1-1 to 1-3.

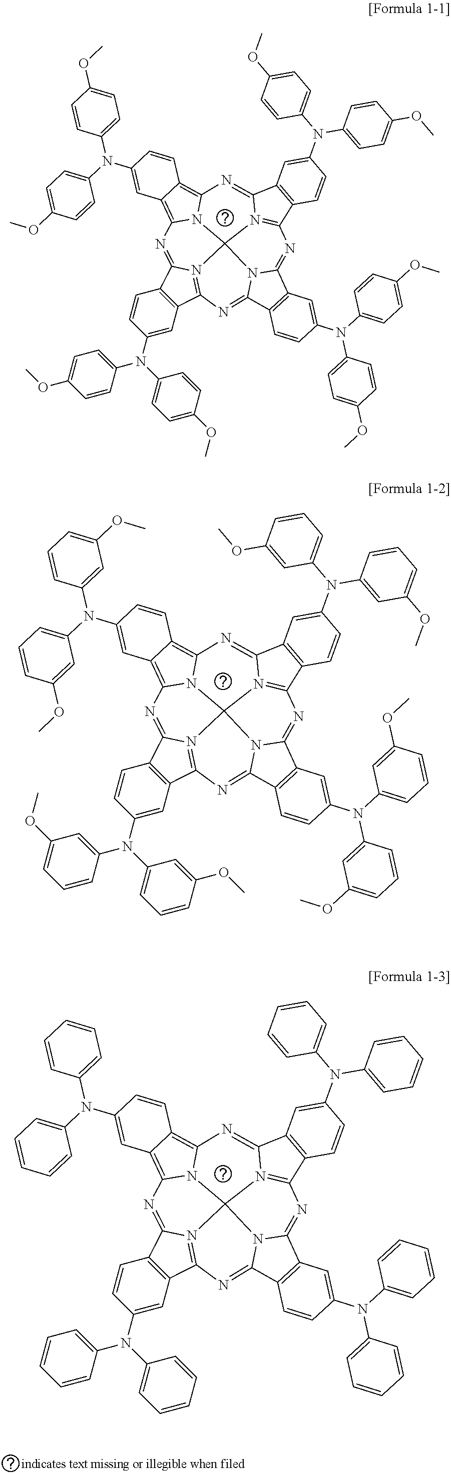

In yet another preferred example of the present invention, the hole transporting material may have a bandgap energy of 1.60 eV or less.

Further, in order to achieve the above-described second object, the present invention provides a method for preparing a perovskite solar cell, the method including: forming an electron transporting layer on a transparent electrode; forming a perovskite photoactive layer on the electron transporting layer; forming a hole transporting layer by treating the perovskite photoactive layer with a solution including the above-described hole transporting material according to one preferred example of the present invention; and forming a counter electrode on the hole transporting layer.

In yet another preferred example of the present invention, a doping process of the hole transporting material may not be performed even in any step before and after the forming of the hole transporting layer.

In yet another preferred example of the present invention, the solution may include the hole transporting material at a concentration of 5 mM to 50 mM.

In yet another preferred example of the present invention, the solution may include at least one selected from chlorobenzene, chloroform, dichlorobenzene, dichloromethane, xylene, and toluene as a solvent.

Furthermore, in order to achieve the above-described third object, the present invention provides a perovskite solar cell including: a transparent electrode; an electron transporting layer formed on the transparent electrode; a perovskite photoactive layer formed on the electron transporting layer; a hole transporting layer formed on the perovskite photoactive layer and including the above-described hole transporting material according to a preferred example of the present invention; and a counter electrode formed on the hole transporting layer.

In a preferred example of the present invention, the perovskite solar cell may satisfy the following Conditions 3) and 4).

$$\begin{matrix}15 \% \leq PCE ( 0 ) \leq 25 \% & 3 ) \\ 50 \% \leq \frac{PCE ( 750 )}{PCE ( 0 )} \leq 80 \% & 4 )\end{matrix}$$

In Conditions 3) and 4), the PCE(0) indicates an initial power conversion efficiency when the perovskite solar cell is exposed under an exposure condition of 100 mW/cm² (AM 1.5 G), and the PCE(750) indicates a power conversion efficiency when the same perovskite solar cell is exposed under the same condition for 750 hours.

In another preferred example of the present invention, the hole transporting layer may have an average thickness of 20 nm to 120 nm.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a view schematically illustrating a layered structure of a perovskite solar cell according to an example of the present invention;

FIG. 2A is a graph illustrating the absorbance of the hole transporting material according to an example of the present invention in a solution according to wavelength;

FIG. 2B is a graph illustrating the absorbance of the hole transporting material according to an example of the present invention in a hole transporting layer according to wavelength;

FIG. 3 is a graph comparing the results of performing a cyclic voltammetry method on the hole transporting materials according to Preparation Examples 1 to 3 of the present invention and Comparative Preparation Example 1;

FIG. 4A is a view illustrating the HOMO energy level (bottom) and LUMO energy level (top) of each layer component and each component of the perovskite solar cell according to an example of the present invention. From the left, a transparent electrode, an electron transporting layer, a perovskite photoactive layer, the hole transporting layer of Example 2, the hole transporting layer of Example 3, and a counter electrode are illustrated;

FIG. 4B is a graph comparing current-voltage characteristics (J-V characteristics) of the perovskite solar cells according to Examples 1 to 3 of the present invention;

FIG. 4C is a graph illustrating the external quantum efficiency of each of the perovskite solar cells according to Examples 1 to 3 of the present invention according to incident wavelength;

FIG. 4D is a frequency distribution view and distribution curve graph illustrating the distribution of the power conversion efficiency measured under an exposure condition of 100 mW/cm² (AM 1.5 G) by preparing a plurality of the perovskite solar cells according to Examples 1 to 3 of the present invention with the same specifications;

FIG. 5A is a graph tracking and illustrating the change in power conversion efficiency over time when the power conversion efficiency of each of the perovskite solar cells according to Example 2 of the present invention and Comparative Example 1 is measured in air under an exposure condition of 100 mW/cm² (AM 1.5 G) and at a temperature of 85° C. and a relative humidity of 55±5%;

FIG. 5B is a graph tracking and illustrating the change in power conversion efficiency over time when the power conversion efficiency of each of the perovskite solar cells according to Example 1 of the present invention and Comparative Example 1 is measured under an exposure condition of 100 mW/cm² (AM 1.5 G) and at a temperature of 85° C. and a relative humidity of 55±5%; and

FIG. 6 illustrates the output of each of the perovskite solar cells according to Examples 1 to 3 of the present invention.

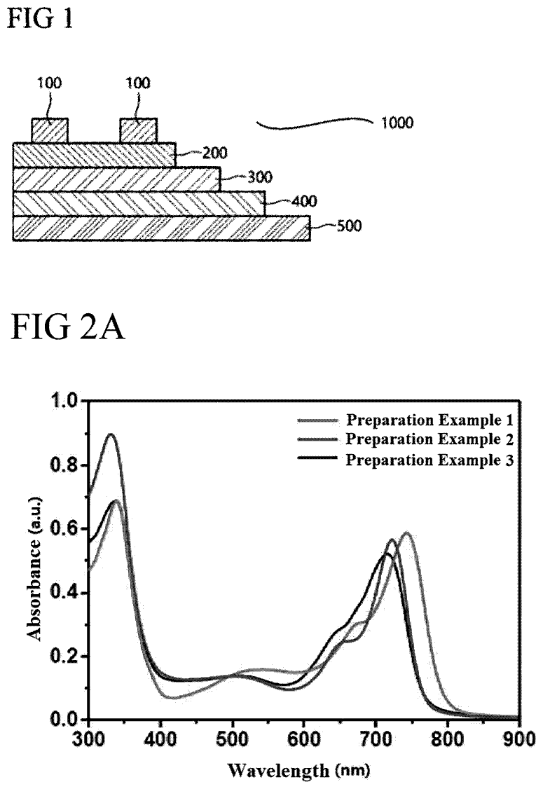

### DETAILED DESCRIPTION OF EXEMPLARY EMBODIMENTS

Exemplary embodiments of the present invention will be described in detail below with reference to the accompanying drawings. While the present invention is shown and described in connection with exemplary embodiments thereof, it will be apparent to those skilled in the art that various modifications can be made without departing from the spirit and scope of the invention.

As described above, a perovskite solar cell which uses an existing spiro compound as a hole transporting material has a problem in that power conversion efficiency is rapidly reduced, and thus performance cannot be secured when the perovskite solar cell is used for a long period of time.

Thus, the present inventors have conducted repeated studies to improve the long-term stability of a perovskite solar cell, and as a result, could aim to improve the long-term stability of the perovskite solar cell by providing a hole transporting material for a perovskite solar cell, which includes a compound represented by the following Formula 1.

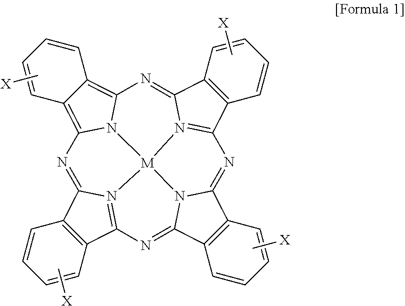

In Formula 1, M is at least one or more metals selected from copper (Cu), zinc (Zn), and cobalt (Co), and X is an electron donating group and each independently includes at least one functional group selected from a C₁₋₁₂ alkyl group consisting of primary to tertiary carbon, benzene, a secondary to tertiary amine group, and a C₁₋₆ linear alkoxy group.

Unlike a spiro compound as a hole transporting material of an existing perovskite solar cell, when the hole transporting material of the present invention is used, there are advantages in that by including the phthalocyanine compound represented by [Formula 1], it is possible to prepare a perovskite solar cell which facilitates packing, has excellent power conversion efficiency even when doping is not performed, and has high long-term stability because the power conversion efficiency is slowly reduced even though a light-harvesting reaction is performed for a long period of time.

At the center of the phthalocyanine-based compound, the central metal forms a coordination bond with a nitrogen atom, and the metal may be, for example, any one selected from copper (Cu), zinc (Zn), and cobalt (Co), but is not limited thereto.

In Formula 1, X is an electron donating group, and the electron density is increased at the center of the phthalocyanine compound due to the presence of X, and holes exhibiting positive charges are transferred better, and thus, hole mobility is enhanced, so that there is an advantage in that power conversion efficiency is improved.

Examples of the electron donating group include electron-rich olefins, alkynes, aryls, alkyl groups, amines, alkoxy groups, and the like, and more preferably, the electron donating group may be a functional group including at least one functional group selected from a C₁₋₁₂ alkyl group consisting of primary to tertiary carbon, benzene, a secondary to tertiary amine group, and a C₁₋₆ linear alkoxy group. When an alkyl group including quaternary carbon is included, there is a problem in that hole mobility is reduced due to the bulky stereochemistry.

More preferably, X may each independently have a structure represented by the following Formula 2.

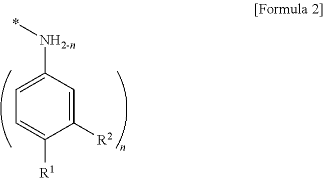

In Formula 2, * is a dangling bond, R₁ and R₂ are each independently hydrogen or a C₁₋₆ linear alkoxy group, and n is 1 or 2.

More preferably, both R₁ and R₂ may be hydrogen, and most preferably, R₁ may be a methoxy group and R₂ may be hydrogen. An alkoxy group is more likely to push electrons than hydrogen, and since a p-substituted alkoxy group pushes electrons better than an n-substituted alkoxy group, the effect of improving the hole mobility of the hole transporting material is much stronger.

Further, in the case of the alkoxy group, the shorter the alkyl portion of the alkoxy group is, the less the alkoxy group has an irregular form, and accordingly, the planar form of the entire molecule may be maintained well, and thus, hole mobility is higher. Accordingly, the methoxy group is most advantageous. When there are six or more carbons, hole mobility may be reduced due to the complexity of the molecular stereochemistry.

Further, a separate dopant may not be included in the hole transporting material. As X is substituted with substituents which are electron-rich and have uncomplicated stereochemistry, the hole transporting material of the present invention is excellent in hole transporting capability (hole mobility) due to the facilitated packing and high electron density, and may have the effect as described above without any dopant. Accordingly, by not doping, a fine structure is disintegrated even though the light-harvesting reaction is repeated, and thus, a problem in that the power conversion efficiency is reduced occurs less, and accordingly, there is an advantage in that the long-term stability is high. In addition, the case where the dopant is not included is freer from the environmental pollution problem, and thus may contribute to the popularization of a solar cell.

If the compound represented by Formula 1 satisfies all of the following Conditions 1) to 3), the compound may have a stereostructure close to a planar form while having a high electron density at the central portion of the molecule, and thus, there is an advantage in that high hole mobility and power conversion efficiency may be realized without any dopant.

$$\begin{matrix}\frac{{n}_{{c}_{π}}}{{n}_{c}} \geq 70 \% & 1 ) \\ 1 \leq {n}_{A} - {N}_{An} \leq 40 & 2 )\end{matrix}$$

3) there is no quaternary carbon in the molecule

In Conditions 1) and 2), n_{c} indicates the total number of carbon atoms, n_{cπ} indicates the number of carbon atoms forming a π bond, n_{A} indicates the total number of atoms except for hydrogen, and n_{Aπ} indicates the number of atoms forming a π bond among the total atoms except for hydrogen.

If Conditions 1) to 3) are not satisfied, the shape of the molecule deviates from the planar shape, and thus, there is a problem in that it is difficult to realize high hole mobility without any dopant.

The hole transporting material may more preferably include at least one selected from compounds represented by the following Formulae 1-1 to 1-3.

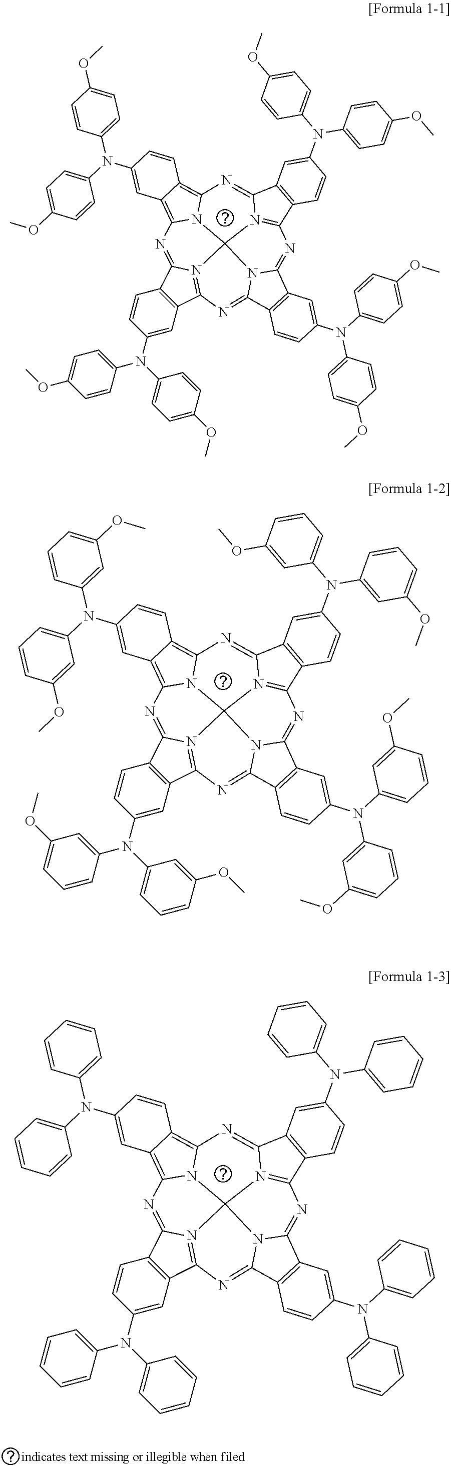

In another preferred example of the present invention, the hole transporting material may have a bandgap energy of 1.60 eV or less. More preferably, the hole transporting material may have a bandgap energy of 1.30 eV to 1.50 eV. The smaller the bandgap energy is, the higher the absorbance is, which is advantageous, but since the open circuit voltage is also lowered, the case where the bandgap energy is within the above range may have the theoretically best power conversion efficiency.

Further, in order to achieve the above-described second object, the present invention provides a method for preparing a perovskite solar cell, the method including: forming an electron transporting layer on a transparent electrode; forming a perovskite photoactive layer on the electron transporting layer; forming a hole transporting layer by treating the perovskite photoactive layer with a solution including the above-described hole transporting material according to one preferred example of the present invention; and forming a counter electrode on the hole transporting layer. By the aforementioned method, it is possible to prepare a perovskite solar cell capable of realizing excellent power conversion efficiency without doping the hole transporting material, and to contribute to the elimination of environmental pollution.

In the forming of the hole transporting layer, the method for treating the perovskite photoactive layer with the solution may be applied with a method generally performed, and the person skilled in the art may easily select and apply such a method from among known methods.

In still another preferred example of the present invention, the solution may include the hole transporting material at a concentration of 5 mM to 50 mM. If the concentration is less than 5 mM, it is difficult to form a clean thin film, and the hole transporting capability may not be sufficient. In contrast, when the concentration is more than 50 mM, hole mobility is lowered, and thus, there may be a problem in that the power conversion efficiency of the solar cell is reduced.

In yet another preferred example of the present invention, the solution may include at least one solvent selected from chloroform, dichloromethane, chlorobenzene, dichlorobenzene, toluene, xylene, and dichloronaphthalene as a solvent. More preferably, the solution may include chlorobenzene as a solvent.

Preferably, a doping process of the hole transporting material may not be performed even in any step before and after the forming of the hole transporting layer. There are advantages by not doping the hole transporting material, that is, the long-term stability of the solar cell may be improved, and environmental pollution may be reduced.

In addition, the content on the method for forming an electron transporting layer, a perovskite photoactive layer, and a counter electrode follows a method applicable within a range that may be easily changed and selected from methods for preparing a perovskite solar cell known in the related art, and is content that is understood by the person skilled in the art without any special explanation.

Furthermore, in order to achieve the above-described third object, the present invention provides a perovskite solar cell including: a transparent electrode; an electron transporting layer formed on the transparent electrode; a perovskite photoactive layer formed on the electron transporting layer; a hole transporting layer formed on the perovskite photoactive layer and including the above-described hole transporting material according to a preferred example of the present invention; and a counter electrode formed on the hole transporting layer. The solar cell has effects of having excellent hole mobility without doping the hole transporting material, and thus has high power conversion efficiency and excellent long-term stability.

Specifically, the perovskite solar cell may satisfy the following Conditions 3) and 4).

$$\begin{matrix}15 \% \leq PCE ( 0 ) \leq 25 \% & 3 ) \\ 50 \% \leq \frac{PCE ( 750 )}{PCE ( 0 )} \leq 80 \% & 4 )\end{matrix}$$

In Conditions 3) and 4), the PCE(0) indicates an initial power conversion efficiency when the perovskite solar cell is exposed under an exposure condition of 100 mW/cm² (AM 1.5 G), and the PCE(750) indicates a power conversion efficiency when the same perovskite solar cell is exposed under the same condition for 750 hours. By satisfying the conditions, the perovskite solar cell may achieve excellent long-term stability, and thus may contribute to the expansion of application of the solar cell.

In yet another preferred example of the present invention, the hole transporting layer may have an average thickness of 20 nm to 120 nm. When the average thickness is less than 20 nm, a sufficient hole transporting capability may not be expressed, and long-term stability may deteriorate because an excessively thin film is formed. In contrast, when the average thickness is more than 120 nm, hole mobility is reduced, and thus, there may be a problem in that power conversion efficiency is reduced.

Hereinafter, the present invention will be described in more detail through the Examples. These Examples are only for exemplifying the present invention, and it will be obvious to a person with ordinary skill in the art that the scope of the present invention is not to be construed as limited by these Examples.

### PREPARATION EXAMPLES

### Preparation Example 1: CuPc-p-PhOMe

A phthalocyanine-based compound represented by the following Formula 3 was synthesized by reacting 4-bromophthalontrile under the reagent conditions as described below.

\textcircled{1} 4-bromophthalontrile; 2 g, 9.66 mmol, copper(II)chloride; 0.87 g, 6.44 mmol, N-pentyl alcohol (1-pentanol; 150 ml), 1,8-diazabicylo[5,4,0]undec-7-ene (DBU); 6.1 ml, 40.57 mmol, 130° C.

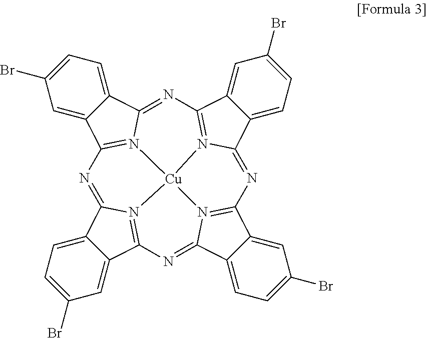

The phthalocyanine-based compound was reacted with p-methoxy substituted diphenylamine represented by the following Formula 4-1 under the following conditions \textcircled{2}.

\textcircled{2} 890 mg (1 mol) of the compound represented by Formula 3, 37 mg (0.04 mmol) of Pd₂(dba)₃, 34 mg (0.06 mmol) of 1,1′-bis(diphenylphosphino)ferrocene (DPPF), 451 mg (4.7 mmol) of sodium tert-butoxide (tBuONa), 90 ml of toluene, 110° C.

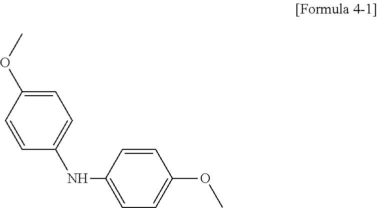 [SMILES: COc1ccc(Nc2ccc(OC)cc2)cc1]

As a result of the reaction, a compound (CuPc-p-PhOMe) represented by the following Formula 1-1 as a hole transporting material was obtained.

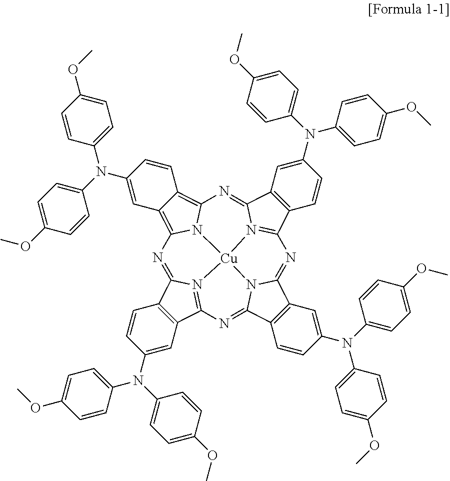

### Preparation Example 2: CuPc-m-PhOMe

Preparation Example 2 was performed in the same manner as in Preparation Example 1, but it differed by using m-methoxy substituted diphenylamine represented by the following Formula 4-2 instead of the p-methoxy substituted diphenylamine represented by Formula 4-1.

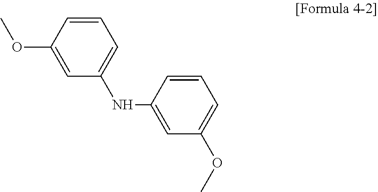 [SMILES: COc1cccc(Nc2cccc(OC)c2)c1]

As a result of the reaction, a compound (CuPc-m-PhOMe) represented by the following Formula 1-2 as a hole transporting material was obtained.

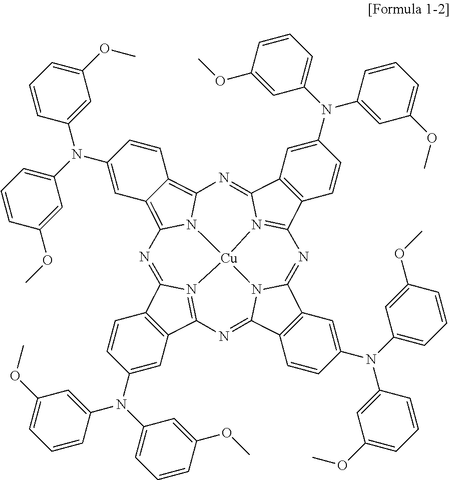

### Preparation Example 3: CuPc-DPh

Preparation Example 3 was performed in the same manner as in Preparation Example 1, but it differed by using diphenylamine having only a benzene ring without a substituent represented by the following Formula 4-3 instead of the p-methoxy substituted diphenylamine represented by Formula 4-1.

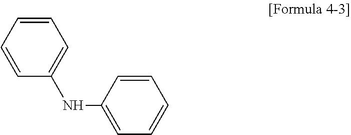 [SMILES: c1ccc(Nc2ccccc2)cc1]

As a result of the reaction, a compound (CuPc-DPh) represented by the following Formula 1-3 as a hole transporting material was obtained.

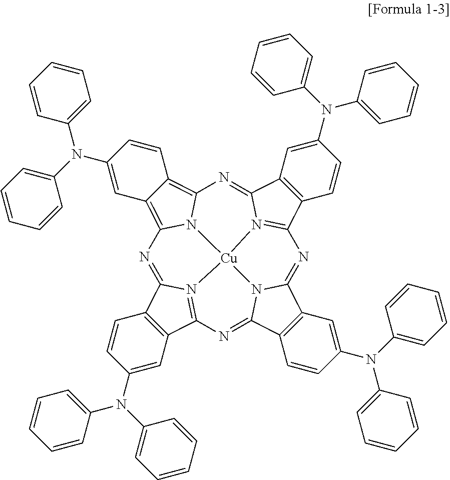

### Comparative Preparation Example 1: Spiro-OMeTAD

A compound (Spiro-OMeTAD) represented by the following Formula 5, used as the hole transporting material, and manufactured by Sigma Aldrich, Inc. (CAS No.: 207739-72-8, Product No.: 792071) was purchased and prepared.

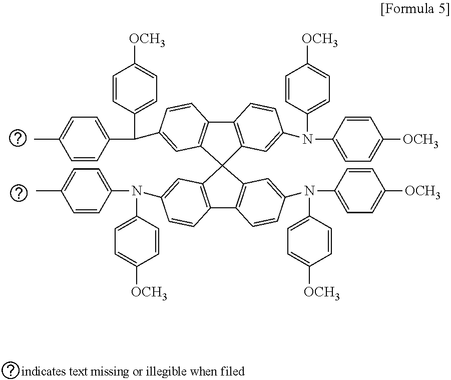 [SMILES: COc1ccc(C(c2ccc(C)cc2)c2ccc3c(c2)C2(c4cc(N(c5ccc(OC)cc5)c5ccc(OC)cc5)ccc4-3)c3cc(N(c4ccc(C)cc4)c4ccc(OC)cc4)ccc3-c3ccc(N(c4ccc(OC)cc4)c4ccc(OC)cc4)cc32)cc1]

Whether the hole transporting materials in Preparation Examples 1 to 3 and Comparative Preparation Example 1 satisfy Conditions 1) to 3) are shown in the following Table 1.

TABLE 1

| | | | | | | Quater- | Condi- | Condi- | Condi- |
|---|---|---|---|---|---|---|---|---|---|
| | | | | | | nary | tion | tion | tion |
| Classification | Material | n_{A} | n_{Aπ} | n_{C} | n_{Cπ} | carbon | 1) | 2) | 3) |
| Preparation | CuPc-p-PhOMe | 109 | 88 | 88 | 80 | None | ∘ | ∘ | ∘ |
| Example 1 | | | | | | | | | |
| Preparation | CuP-m-PhOMe | 109 | 88 | 88 | 80 | None | ∘ | ∘ | ∘ |
| Example 2 | | | | | | | | | |
| Preparation | CuPc-DPh | 93 | 88 | 80 | 80 | None | ∘ | ∘ | ∘ |
| Example 3 | | | | | | | | | |
| Comparative | Spiro-OMeTAD | 93 | 72 | 81 | 72 | 1 | ∘ | ∘ | x |
| Preparation | | | | | | | | | |
| Example 1 | | | | | | | | | |

Referring to Table 1, the hole transporting materials in Preparation Examples 1 to 3 have a high proportion of atoms forming a π bond and do not have a quaternary carbon in the molecule, and thus have a molecular structure close to a planar shape, and the hole transporting material of Comparative Preparation Example 1 has a quaternary carbon, and has a high proportion of atoms that do not form a π bond, and thus, the molecular structure thereof usually has a bulkier form.

### EXAMPLES

### Example 1: Preparation of Perovskite Solar Cell

Before UV ozone was used, an ITO substrate was washed with acetone and isopropyl alcohol for 20 minutes. ZnO-EAL was prepared by sol-gel conversion. After a ZnO sol-gel solution was spin-coated onto an ITO/glass substrate at 2,000 rpm for 15 seconds, the substrate was annealed at 140° C. for 10 minutes so as to have a thickness of 40 nm. Subsequently, the substrate was coated with a WPF polymer electrolyte. A perovskite layer was sequentially deposited and prepared. A mixture of 461 mg of PbI₂ and 78 mg of DMSO (molar ratio of 1:1) using DMF as a solvent was heated at 100° C. for 2 hours. After the PbI₂ solution was spin-coated (3,000 rpm, 20 seconds) onto the ZnO—WPF substrate, heat annealing was performed at 100° C. for 3 minutes. After a cooling process was performed, the PbI₂ layer was immersed in a methylammonium iodide (MAI) solution using 2-propanol (0.25 M) as a solvent for 1 minute. After an excessive amount of MAI was removed by immersing the film in a 2-propanol solution for 20 seconds, a perovskite layer was obtained by performing heat treatment at 100° C. for 10 minutes. A hole transporting layer solution was spin-coated (4,000 rpm, 30 seconds), and the hole transporting layer solution is a solution including the hole transporting material for a perovskite solar cell at a concentration of 40 mM in chlorobenzene.

A hole transporting layer had a thickness of about 50 nm. All the preparation processes in the present Example were performed in air. Finally, an Au positive electrode (100 nm) was deposited using heat evaporation under low pressure (<10⁻⁶ Torr) using a metal mask, such that the active pressure was 70.7 mm².

### Example 2: Preparation of Perovskite Solar Cell

Example 2 was performed in the same manner as in Example 1, but it differed by using the hole transferring material prepared in Preparation Example 2 as a hole transferring material.

### Example 3: Preparation of Perovskite Solar Cell

Example 3 was performed in the same manner as in Example 1, but it differed by using the hole transporting material prepared in Preparation Example 3 as a hole transporting material.

### Comparative Example 1: Preparation of Perovskite Solar Cell

Comparative Example 1 was performed in the same manner as in Example 1, but it differed by forming a hole transporting layer by applying a solution including the hole transporting material prepared in Comparative Preparation Example 1 at a concentration of 65 mM as the hole transporting material in the forming of the hole transporting layer and using chlorobenzene as a solvent.

### EXPERIMENTAL EXAMPLES

### Experimental Example 1: Measurement of UV-Visible Light Absorbance and Bandgap

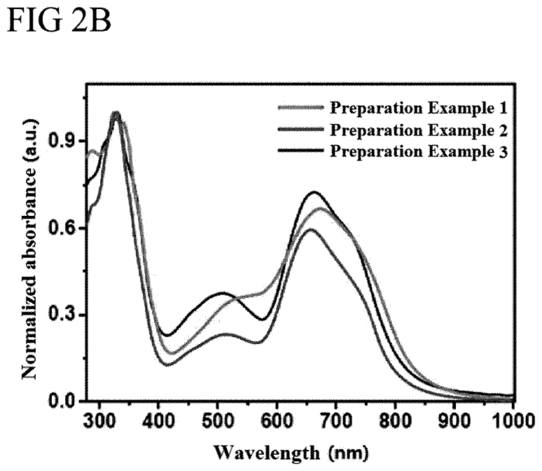

The absorbance was observed using a UV-Vis-NIR spectrometer (S-3100, Scinco Co., Ltd.) in a state where the hole transporting materials in Preparation Examples 1 to 3 were dispersed at a concentration of 10 mg/ml in a chloroform solvent and in a state of a film by applying the dispersed solution to a thickness of 100 nm and drying, respectively, and the results thereof are illustrated in FIGS. 2A and 2B, respectively.

The peak information of the absorbance in the solution state and the film state is shown in the following Table 2.

TABLE 2

| | Hole transferring | Solution state | Film state |
|---|---|---|---|
| Classification | material | peak (nm) | peak (nm) |
| Preparation Example 1 | CuPc-p-PhOMe | 338, 744 | 333, 674 |
| Preparation Example 2 | CuPc-m-PhOMe | 331, 722 | 333, 656 |
| Preparation Example 3 | CuPc-DPh | 336, 715 | 333, 663 |

### Experimental Example 2: Cyclic Voltammetry Measurement of Hole Transporting Material in Solution

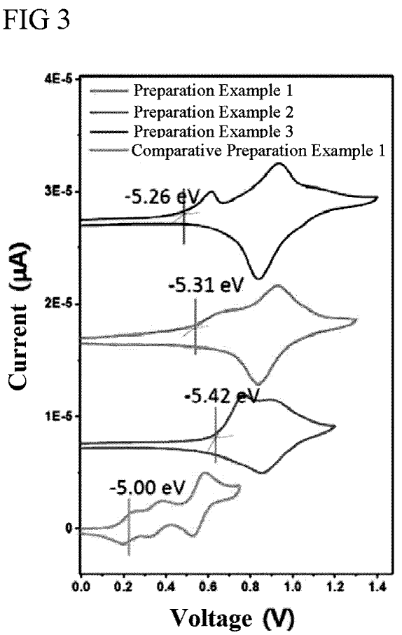

A cyclic voltammetry method was performed on the hole transporting materials in Preparation Examples 1 to 3 and Comparative Preparation Example 1, and the results thereof are illustrated in FIG. 3.

### Experimental Example 3: Measurement of External Quantum Efficiency

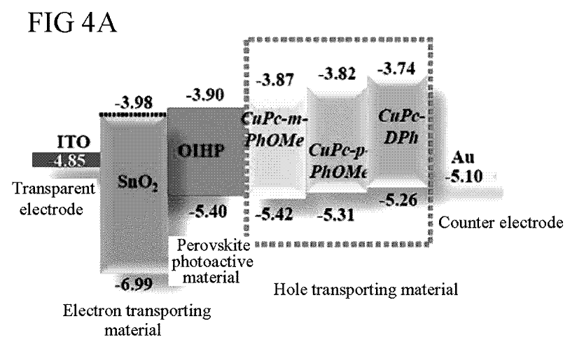

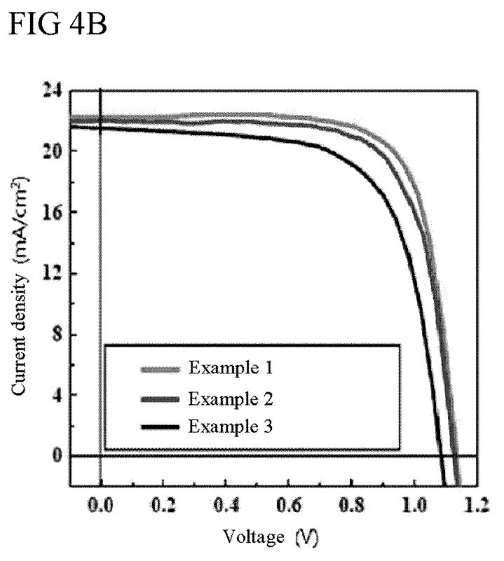

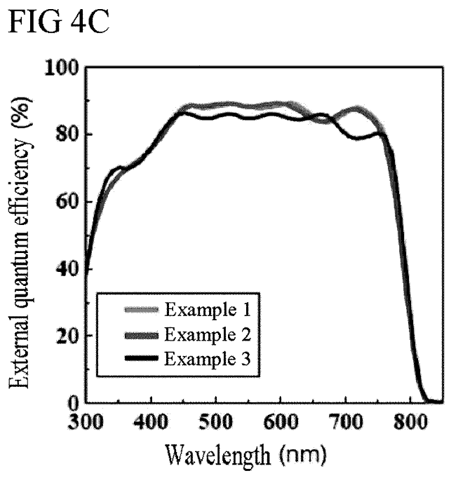

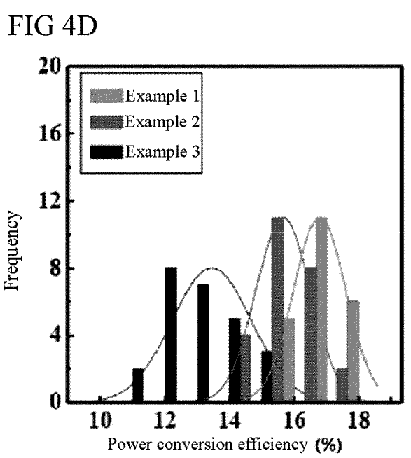

For each of the perovskite solar cells of Examples 1 to 3, light emitted from a silver 400 W xenon lamp was allowed to pass through a monochromator, and was obtained using an alignment filter. The collimated output of the monochromatic device was measured through a 1 mm aperture (McScience, K3100 IQX). Calibration was performed using a silicon photodiode standard. Wavelength values were scanned from 300 nm to 850 nm at a chopping frequency of 4 Hz. An obtained external quantum efficiency curve is illustrated in FIG. 4C.

Referring to FIG. 4C, it could be seen that the external quantum efficiency curve of the perovskite solar cells prepared according to Examples 1 to 3 predominantly showed an external quantum efficiency of 80% or more and showed excellent performance except for some regions below 450 nm and above 750 nm.

### Experimental Example 4: Measurement of Fill Factor (FF)

The J-V curves of the perovskite solar cells prepared according to Examples 1 to 3 are each shown in FIG. 4B, and the short-circuit current (J_{SC}), open circuit voltage (V_{OC}), and fill factor are shown in the following Table 3.

TABLE 3

| | Hole | PCE | V_{OC} | J_{SC} | |
|---|---|---|---|---|---|
| Classification | transporting material | (%) | (V) | (mA · cm⁻²) | FF |
| Example 1 | CuPc-p-PhOMe | 18.06 | 1.13 | 22.26 | 0.72 |
| Example 2 | CuPc-m-PhOMe | 17.12 | 1.12 | 22.07 | 0.70 |
| Example 3 | CuPc-DPh | 15.54 | 1.10 | 21.67 | 0.65 |

### Experimental Example 5: Measurement of Power Conversion Efficiency and Long-Term Stability

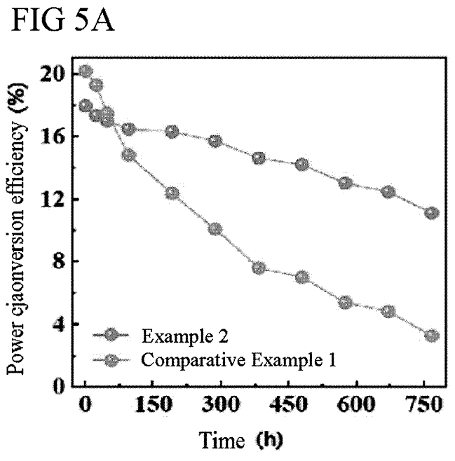

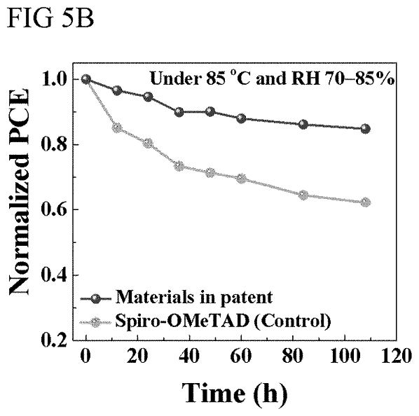

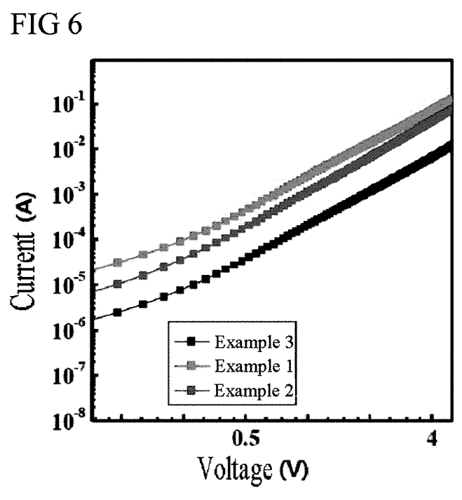

The perovskite solar cells of Examples 1 to 3 and Comparative Example 1 were provided and the power conversion efficiency (PCE) was measured under the conditions of a light intensity of 100 mW/cm² (AM 1.5 G), 25° C., in air, and a relative humidity of 55±5%. The initial power conversion efficiency of each of the perovskite solar cells of Examples 1 to 3 are shown in Table 3, the perovskite solar cells of Example 2 and Comparative Example 1 were left to stand under the above conditions for up to 750 hours to continuously produce electricity, and the change in power conversion efficiency over time is shown in FIG. 5A.

Different perovskites of Example 1 and Comparative Example 1, which were prepared by the same method, were placed under a condition of 85° C. while the other conditions are the same, and the change in power conversion efficiency for 110 hours while producing electricity is shown in FIG. 5B.

Referring to FIGS. 5A and 5B, it can be seen that the perovskite solar cell of the Example according to the present invention shows an initial power conversion efficiency at both room temperature and 85° C. that is slightly low as compared to the perovskite solar cell of Comparative Example 1, in which a spiro compound is used as the hole transporting material, but unlike the perovskite solar cell of Comparative Example 1, in which the power conversion efficiency is sharply reduced as time elapses, the perovskite solar cell according to the present invention has a slowly reduced power conversion efficiency, and thus, exhibits a power conversion efficiency more than twice that of the perovskite solar cell of the Comparative Example after 750 hours at room temperature, and exhibits a power conversion efficiency about twice that of the perovskite solar cell of the Comparative Example after about 110 hours even at 85° C.

Accordingly, it can be seen that the perovskite solar cell using the hole transporting material according to the present invention is excellent in initial power conversion efficiency and is also excellent in long-term stability.

### Experimental Example 6: Measurement of Hole Mobility

The hole mobility of each of the solar cells of Examples 1 to 3 were calculated according to the following General Formula 1, and is shown in the following Table 4.

TABLE 4

| | | Hole mobility |
|---|---|---|
| Classification | Hole transporting material | (cm² · V⁻¹ · s⁻¹) |
| Example 1 | CuPc-p-PhOMe | 6.3 × 10⁻⁴ |
| Example 2 | CuPc-m-PhOMe | 5.1 × 10⁻⁴ |
| Example 3 | CuPc-DPh | 3.4 × 10⁻⁴ |

Referring to Table 4, it could be seen that the case where the methoxy group pushing electrons was para-substituted had the most significant electron-pushing effect, and thus, the hole mobility of Example 1 was shown to be the highest.

The hole transporting material for a perovskite solar cell according to the present invention has a small bandgap and high hole mobility, and can excellently maintain the above-described physical properties even for a long term operation.

Further, it is possible to prepare a hole transporting material for a perovskite solar cell, which has mechanical and electrical characteristics which are the same as those described above by the method according to the present invention.

In addition, the perovskite solar cell according to the present invention has an advantage in that a high power conversion efficiency can be maintained even when operated for a long period of time while an object of realizing a high power conversion efficiency which is almost similar to that of an existing high-efficiency solar cell can be achieved.

It will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

What is claimed is:

1. A hole transporting material for a perovskite solar cell, comprising a compound represented by the following Formula 1: 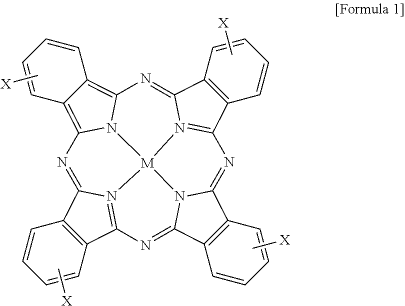
in Formula 1, M is at least one or more metals selected from copper (Cu), zinc (Zn), and cobalt (Co), and X is an electron donating group and each independently includes at least one functional group selected from a C₁₋₁₂ alkyl group consisting of primary to tertiary carbon, benzene, a secondary to tertiary amine group, and a C₁₋₆ linear alkoxy group.

2. The hole transporting material of claim 1, wherein a separate dopant is not comprised in the hole transporting material.

3. The hole transporting material of claim 1, wherein the compound represented by Formula 1 satisfies all of the following Conditions 1) to 3):
$$\begin{matrix}\frac{{n}_{{c}_{π}}}{{n}_{c}} \geq 70 \% & 1 ) \\ 1 \leq {n}_{A} - {N}_{An} \leq 40 & 2 )\end{matrix}$$
3) there is no quaternary carbon in the molecule
in Conditions 1) and 2), n_{c} indicates the total number of carbon atoms in the hole transporting material molecule, n_{cπ} indicates the number of carbon atoms forming a π bond, n_{A} indicates the total number of atoms except for hydrogen in the, and n_{Aπ} indicates the number of atoms forming a π bond among the total atoms except for hydrogen.

4. The hole transporting material of claim 1, wherein X each independently has a structure represented by the following Formula 2: 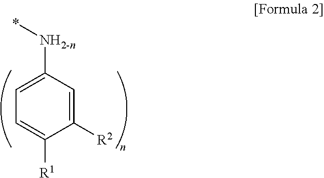
in Formula 2, * is a dangling bond, R¹ and R² are each independently hydrogen or a C₁₋₆ linear alkoxy group, and n is 1 or 2.

5. The hole transporting material of claim 4, wherein the compound represented by Formula 1 is any one selected from compounds represented by the following Formulae 1-1 to 1-3:

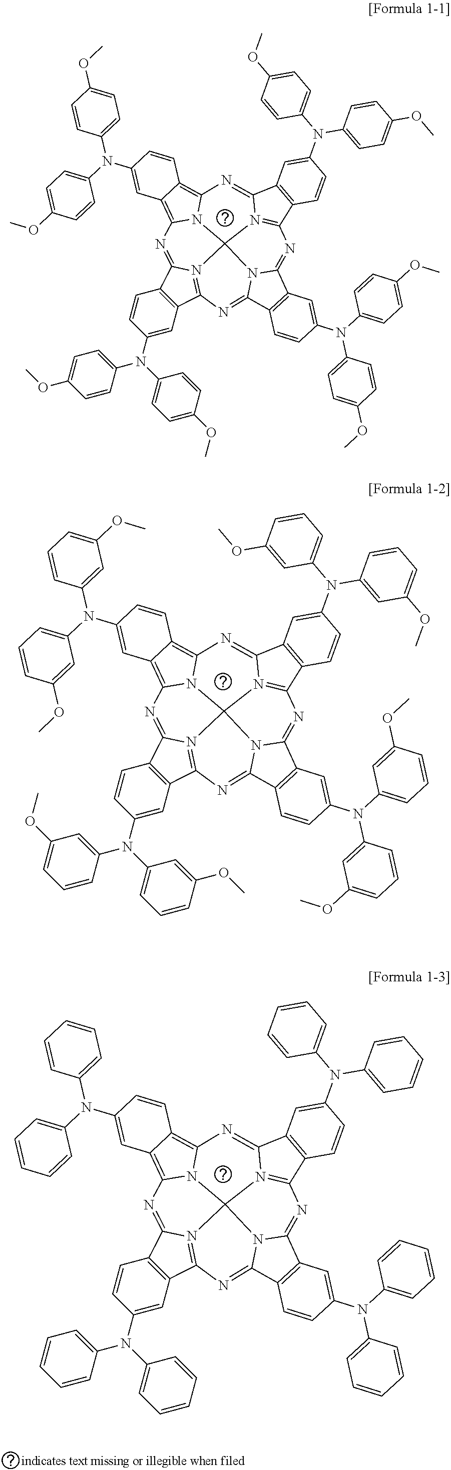

6. The hole transporting material of claim 1, wherein the hole transporting material has a bandgap energy of 1.60 eV or less.

7. A method for preparing a perovskite solar cell, the method comprising:
forming an electron transporting layer on a transparent electrode;
forming a perovskite photoactive layer on the electron transporting layer;
forming a hole transporting layer by treating the perovskite photoactive layer with a solution comprising the hole transporting material of claim 1; and
forming a counter electrode on the hole transporting layer.

8. The method of claim 7, wherein a doping process of the hole transporting material is not performed even in any step before and after the forming of the hole transporting layer.

9. The method of claim 7, wherein the solution comprises the hole transporting material at a concentration of 5 mM to 50 mM.

10. The method of claim 9, wherein the solution comprises at least one solvent selected from chlorobenzene, toluene, xylene, chloroform, dichlorobenzene, and dichloromethane.

11. A perovskite solar cell comprising:
a transparent electrode;
an electron transporting layer formed on the transparent electrode;
a perovskite photoactive layer formed on the electron transporting layer;
a hole transporting layer formed on the perovskite photoactive layer and comprising the hole transporting material of claim 1; and
a counter electrode formed on the hole transporting layer.

12. The perovskite solar cell of claim 11, wherein the perovskite solar cell satisfies the following Conditions 3 and 4):
$$\begin{matrix}15 \% \leq PCE ( 0 ) \leq 25 \% & 3 ) \\ 50 \% \leq \frac{PCE ( 750 )}{PCE ( 0 )} \leq 80 \% & 4 )\end{matrix}$$
in Conditions 3) and 4), the PCE(0) indicates an initial power conversion efficiency when the perovskite solar cell is exposed under an exposure condition of 100 mW/cm² (AM 1.5 G), and the PCE(750) indicates a power conversion efficiency when the same perovskite solar cell is exposed under the same exposure condition for 750 hours.

13. The perovskite solar cell of claim 11, wherein the hole transporting layer has an average thickness of 20 nm to 120 nm.
